(19) United States
(12) Patent Application Publication
(10) Pub. No.: US 2007/0224706 A1
(43) Pub. Date: Sep. 27, 2007

(54) Method of producing semiconductor device and semiconductor device

(75) Inventor: Kazutoshi Izumi, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/638,422

(22) Filed: Dec. 14, 2006

(30) Foreign Application Priority Data
Mar. 27, 2006 (JP) 2006-086557

(51) Int. Cl. H01L 21/00

(52) U.S. Cl. 438/3

(57) ABSTRACT

In the production of a semiconductor device in which a ferroelectric capacitor is used as a memory, a method of producing the semiconductor device in which the oxidation of a tungsten film embedded in an alignment mark prepared in the form of a groove is prevented includes forming an oxidation-preventing film composed of P—SiN (SiON) to cover the tungsten film prior to the formation of the ferroelectric capacitor, and heat-treating the oxidation-preventing film so as to thermally contract the film in advance.

### BACKGROUND OF THE INVENTION

1. Field of the Invention

The present invention relates to a method of producing a semiconductor device, in particular, to a method of producing a semiconductor device in which when a ferroelectric substance is heat-treated in an oxygen atmosphere in the formation of a ferroelectric capacitive element of a ferroelectric random access memory (FRAM), the oxidation of a tungsten (W) film embedded in a groove of an alignment mark can be prevented, and a semiconductor device produced by the method.

2. Description of the Related Art

A ferroelectric memory including a ferroelectric thin-film serving as a capacitive element (capacitor) is a randomly accessible nonvolatile memory and is referred to as ferroelectric random access memory (hereinafter abbreviated as FRAM). The FRAM has features such as low-voltage operation, high durability, and low power consumption. Therefore, the FRAM is considered to be an ideal memory, and thus research and development of the FRAM has been actively performed recently.

In the FRAM, at least one transistor and at least one ferroelectric capacitive element are combined to form a set, and a capacitive element connected to one of diffusion layers of a selection transistor is used as a memory cell that stores information of 1 bit.

In the ferroelectric capacitor constituting the memory cell, a ferroelectric thin-film composed of a metal oxide such as strontium bismuth tantalate or lead zirconate titanate, which is abbreviated to SBT or PZT, respectively, is used as a capacitor insulating film constituting the capacitor. Information is permanently stored by polarizing the ferroelectric substance.

The ferroelectric substance causes spontaneous dielectric polarization in the low temperature phase. This polarization can be reversed by an external electric field, and thus has a hysteresis characteristic. That is, when the polarity of the voltage applied is switched, a plus or minus charge can be induced on the surface of the ferroelectric substance. Furthermore, even when the voltage supply is stopped, the electric charge can be held. Accordingly, by assigning the above states to 0 and 1 of logic, a memory can be formed.

A FRAM having a 2T2C cell structure combining two transistors and two capacitive elements has been widely used. However, because of improvements in the circuit system of the cell and the structure of the capacitive element; demands for a reduction in the cell size, an increase in the integration of the structure, an increase in capacity as a memory, and the like, the structure of the FRAM has been changed to a 1T1C cell structure.

In the FRAM, the structure of the ferroelectric capacitive element is also important. At first, the ferroelectric capacitor had a planar structure in which a ferroelectric film was sandwiched between two plate electrodes. Recently, the thickness of the ferroelectric film has been decreased to several hundreds of nanometers to several tens of nanometers. On the other hand, in order to further reduce the cell size, improved structures such as a stack structure on a plug and a three-dimensional stack structure have been developed.

FIG. 5A is a schematic cross-sectional view of an example of a known FRAM. In FIG. 5A, a transistor 101 and a capacitive element 102 composed of a ferroelectric substance form a set, and are connected to each other via, for example, tungsten (W) wiring 5 composed of a high melting point metal in the vertical direction to form a planar structure. A plurality of sets corresponding to the bit capacity of a memory are provided on a substrate 6.

Alignment marks 1, which are used for alignment in the production preprocess such as exposure, are provided on a plurality of positions on the peripheral part of the substrate 6. The alignment marks 1 are formed so as to be strong, i.e., so as not to be damaged or removed in the course of the production process.

Specifically, in a step of forming a plug 7 attached to the transistor 101, each of the alignment marks 1 is formed at the same time by a damascene process as follows. A groove 10 is formed, a metal such as W used for the wiring is embedded in the groove 10, and the W is then polished by chemical mechanical polishing (CMP).

The ferroelectric substance constituting the capacitive element is composed of a metal oxide crystal. Therefore, in the production process of the FRAM, a heat treatment is essentially performed in an oxygen atmosphere at a high temperature so that the FRAM exhibits an ideal hysteresis characteristic by having crystal defects of the ferroelectric substance removed or recovering from process damage suffered during steps such as sputtering and etching.

Accordingly, for example, wiring and the alignment marks used in a step of exposure or the like, which are produced prior to the formation of the ferroelectric capacitive element and are composed of a high melting point metal such as W, are oxidized by the heat treatment performed in an oxygen atmosphere unless a protective measure is taken.

Consequently, at the wiring or the like, conductivity of the metal is lost due to the formation of an insulating oxide. At the alignment marks, the oxide protrudes to generate deformation, resulting in degradation of the accuracy of the alignment.

Accordingly, regarding the production process of the FRAM, a heat treatment performed in an oxygen atmosphere at a high temperature, which is essential to the production of a ferroelectric capacitive element, and a protective measure against the oxidation of a metal pattern caused by the heat treatment have been proposed.

The oxidation of metal wiring provided under a ferroelectric capacitor is prevented by forming at least one metal wiring layer, forming the top metal wiring layer, forming an oxidation-preventing film, forming a ferroelectric capacitor, and performing a heat treatment in an oxygen atmosphere, in that order. Thus, the oxidation of the metal wiring is prevented (for example, see Japanese Unexamined Patent Application Publication No. 2001-217397).

The significant oxidation of a tungsten mark (alignment mark) caused by a heat treatment under an oxygen atmosphere during the formation of a ferroelectric substance is prevented by forming a metal film in a groove provided on an insulating film, forming an oxidation-preventing film thereon. Thus, oxygen is blocked to prevent the oxidation. Furthermore, examples of the method of preventing such oxidation include forming a second insulating film, forming a groove in a step of forming a contact hole, forming a metal film in a step of embedding a contact hole, and forming an iridium film for preventing the oxidation of a metal (for example, see Japanese Patent No. 3519721 ([0015] to [0017]). Thus, the oxidation of wiring and alignment marks caused by a heat treatment in an oxygen atmosphere, which is essential in the production of the FRAM, is generally prevented by forming an oxidation-preventing film. For example, a P—SiN (SiON) film formed by plasma deposition is often used as the oxidation-preventing film.

In FIG. 5A, the plug 7 is a small hole having a diameter L1 of about 0.3 μm and a depth of about 0.7 μm. Therefore, as shown in a cross-sectional image of FIG. 5B, it is easy to embed W serving as a conductive metal in the plug 7. In addition, even when a heat treatment is performed in an oxygen atmosphere, in the case where the surface of the plug 7 is covered with an oxidation-preventing film composed of P—SiN (SiON), W is not oxidized.

In contrast, regarding the alignment mark 1, which is used for optical alignment during an exposure step or the like, the width of the mark requires at least L2=2 μm. That is, the alignment mark 1 is larger than the plug 7 to a different order of magnitude.

Therefore, in a groove peripheral part 11 of the alignment mark 1 surrounded by the circle shown in FIG. 5A, the following problem occurs. As shown in an enlarged cross-sectional image of FIG. 5C, when W is not satisfactorily embedded in the alignment mark 1 prepared in the form of a groove, at the groove peripheral part 11, large irregularities are formed on the surface of a W film 2. Consequently, the coverage (covering performance) of an SiON oxidation-preventing film 3 formed thereon is not satisfactory.

FIGS. 6A and 6B show a state of the oxidation of the alignment mark. FIG. 6A is an enlarged surface image and FIG. 6B is a scanning electron microscope (SEM) image of the cross-section. As shown in these images, in the alignment mark 1 including the W film 2, W is oxidized by the heat treatment in an oxygen atmosphere, and rises and protrudes over the side of the mark. Consequently, sharpness is lost from the outline of the mark, resulting in a deformation of the outline.

As described above, in the production process of the FRAM, according to a process in which an alignment mark is formed prior to the formation of a ferroelectric capacitive element, that is, the alignment mark is simultaneously formed with a plug extending from a transistor, W constituting the alignment mark is disadvantageously oxidized by a subsequent heat treatment of a ferroelectric substance in an oxygen atmosphere.

Specifically, when the thickness of W embedded in the alignment mark prepared in the form of a groove is small, W is not satisfactorily embedded in the groove. Therefore, when the P—SiN (SiON) oxidation-preventing film has a small thickness, a satisfactory coverage of the groove peripheral part cannot be achieved, resulting in abnormal oxidation of W during the heat treatment of the ferroelectric substance in an oxygen atmosphere. In contrast, an increase in the thickness of W for the purpose of sufficiently embedding W causes problems such as an increase in the deposition time of the W film, an increase in the polishing time by CMP, and peeling of the W film due to high stress.

On the other hand, when the thickness of the P—SiN (SiON) oxidation-preventing film is increased, a thermal contraction of the film occurs during the heat treatment of the ferroelectric substance in an oxygen atmosphere, resulting in peeling of the upper film. When the heat treatment is performed at 650° C. in an oxygen atmosphere, the degree of the thermal contraction of the P—SiN (SiON) film is 30% or more. Furthermore, when the thickness of the P—SiN (SiON) film is increased, it is difficult to perform etching for forming a contact hole at the position of the plug, resulting in defective conduction.

### SUMMARY OF THE INVENTION

Accordingly, it is an object of the present invention to provide a method of producing a semiconductor device in which when a ferroelectric substance is heat-treated in an oxygen atmosphere in the production process of the FRAM, the oxidation of a W film embedded in a groove of an alignment mark can be prevented. It is another object of the present invention to provide a semiconductor device produced by the method.

The above-described problems can be solved by the following methods. In claim 1, in the production of a semiconductor device in which a ferroelectric capacitor is used as a memory, a method of producing the semiconductor device in which the oxidation of a tungsten (W) film embedded in an alignment mark prepared in the form of a groove is prevented includes forming an oxidation-preventing film composed of P—SiN (SiON) to cover the W film prior to the formation of the ferroelectric capacitor, and heat-treating the oxidation-preventing film so as to thermally contract the film in advance.

In order to stably form a ferroelectric capacitive element of the FRAM, a ferroelectric substance is heat-treated in an oxygen atmosphere. In this case, an oxidation-preventing film composed of P—SiN (SiON) is used in order to prevent the oxidization of a W film embedded in a groove of an alignment mark.

However, it is known that P—SiN (SiON) is contracted by 30% or more by the heat treatment at 650° C. in an oxygen atmosphere. Therefore, P—SiN (SiON) cannot satisfactorily function as the oxidation-preventing film of the W film.

Consequently, in the present invention, before a ferroelectric substance is heat-treated in an oxygen atmosphere, the oxidation-preventing film composed of P—SiN (SiON) is heat-treated to be contracted in advance. Thus, during the heat treatment of the ferroelectric substance in an oxygen atmosphere, the abnormal oxidation of the W film caused by an insufficient coverage due to the thermal contraction is prevented.

In claim 2, in the production of a semiconductor device in which a ferroelectric capacitor is used as a memory, a method of producing the semiconductor device in which the oxidation of a W film embedded in an alignment mark prepared in the form of a groove is prevented includes polishing the W film by CMP, performing etch back so as to remove a part of the W film disposed at the groove peripheral part of the alignment mark, and forming an oxidation-preventing film composed of P—SiN (SiON) to cover the W film.

In this method, first, the W film embedded in the groove of the alignment mark is polished by CMP to smoothen the surface. Subsequently, etch back is performed so that a part of the W film that grows in an irregular form and that is disposed on the groove peripheral part of the alignment mark is removed so as to smoothen the W film.

In this case, when the oxidation-preventing film composed of P—SiN (SiON) is then deposited on the W film, the coverage of the oxidation-preventing film for the W film can be increased. Consequently, during the heat treatment of the ferroelectric substance in an oxygen atmosphere, the abnormal oxidation of the W film caused by an insufficient coverage due to the thermal contraction can be prevented.

In claim 3, in the production of a semiconductor device in which a ferroelectric capacitor is used as a memory, a method of producing the semiconductor device in which the oxidation of a W film embedded in an alignment mark prepared in the form of a groove is prevented includes forming an oxidation-preventing film composed of P—SiN (SiON) to cover the W film, polishing the oxidation-preventing film by CMP, and again forming an oxidation-preventing film to cover the W film.

In this method, first, an oxidation-preventing film composed of P—SiN (SiON) is formed so as to cover the W film embedded in the groove of the alignment mark. Subsequently, the oxidation-preventing film is polished by CMP, thus removing a part of the oxidation-preventing film whose coverage is not satisfactory because the surface shape of the film follows irregularities of the W film provided thereunder. Subsequently, an oxidation-preventing film is again formed so as to cover the W film.

Thus, the W film is first covered with the oxidation-preventing film, the oxidation-preventing film is then polished by CMP, and the W film is again covered with an oxidation-preventing film. Although the number of steps is increased, this method can prevent the abnormal oxidation of the W film due to a problem of insufficient coverage of the oxidation-preventing film, resulting in an increase in the production efficiency.

In claim 4, in the production of a semiconductor device in which a ferroelectric capacitor is used as a memory, a method of producing the semiconductor device in which the oxidation of a W film embedded in an alignment mark prepared in the form of a groove is prevented includes polishing the W film by CMP, and forming an SOG film in the groove of the alignment mark.

In order to eliminate irregularities of the W film deposited on the groove peripheral part of the alignment mark, when the W film is formed so that the groove is completely embedded with the W film, the deposition process requires a considerably long time and such a process is not practical. Consequently, in the present invention, the W film is polished by CMP, and an SOG film, which has high deposition efficiency and requires a short deposition time, is then formed so as to cover irregularities of the W film disposed on the groove peripheral part of the alignment mark.

In this case, the W film deposited on the groove peripheral part of the alignment mark is satisfactorily covered. Consequently, even when the heat treatment of the ferroelectric substance in an oxygen atmosphere is performed in the subsequent step, the abnormal oxidation of the W film due to the problem of insufficient coverage can be prevented.

In order to further improve the performance of the P—SiN (SiON) film as the oxidation-preventing film, i.e., the coverage performance, in claim 5, in the method of producing a semiconductor device according to any one of claims 1, 2, 3, and 4, the P—SiN (SiON) film is preferably a high-density plasma film. In claim 6, in the method of producing a semiconductor device according to any one of claims 1, 2, 3, and 4, a plasma treatment using N₂ or N₂O in the range of 200° C. to 450° C. is preferably performed. Furthermore, in claim 7, in the method of producing a semiconductor device according to any one of claims 1, 2, 3, and 4, the P—SiN (SiON) film is preferably formed using SiH₄ and N₂O gas.

Furthermore, in claim 8, in the method of producing a semiconductor device according to any one of claims 1, 2, 3, and 4, the oxidation-preventing film composed of P—SiN (SiON) is formed, and an oxide film that is composed of P—SiO and that has a refractive index in the range of 1.45 to 1.65 may then be formed. In claim 9, in the method of producing a semiconductor device according to any one of claims 1, 2, 3, and 4, the oxidation-preventing film composed of P—SiN (SiON) is formed, and a hydrogen-diffusion-preventing film composed of Al₂O₃ may then be formed.

That is, in claims 8 or 9, the oxidation-preventing film composed of P—SiN (SiON) can prevent the oxidation of the W film in the groove of the alignment mark, and in addition, the orientation of a film that is composed of Ti, Pt, or the like and that functions as a lower electrode of the ferroelectric capacitive element can be improved.

In claim 10, the above-described problems can be solved by a semiconductor device produced by the method of producing a semiconductor device according to any one of claims 1, 2, 3, and 4.

The present invention improves the coverage of a P—SiN (SiON) oxidation-preventing film that covers a W film embedded in a groove-shaped alignment mark used in the production process of the FRAM.

Consequently, even when a ferroelectric substance is heat-treated in an oxygen atmosphere in the formation of a ferroelectric capacitive element, the oxidation of the W film can be prevented. Therefore, the alignment mark can be used with an original high accuracy, and thus the FRAM can be efficiently produced.

### BRIEF DESCRIPTION OF THE DRAWINGS

FIGS. 1A and 1B are schematic cross-sectional views of the relevant part of a first embodiment of the present invention;

FIGS. 2A and 2B are schematic cross-sectional views of the relevant part of a second embodiment of the present invention;

FIGS. 3A to 3C are schematic cross-sectional views of the relevant part of a third embodiment of the present invention;

FIGS. 4A and 4B are schematic cross-sectional views of the relevant part of a fourth embodiment of the present invention;

FIG. 5A is a schematic cross-sectional view of an example of a known FRAM;

FIGS. 5B and 5C are cross-sectional images of an example of the known FRAM; and

FIGS. 6A and 6B are images each showing a state of the oxidation of an alignment mark.

### DESCRIPTION OF THE PREFERRED EMBODIMENTS

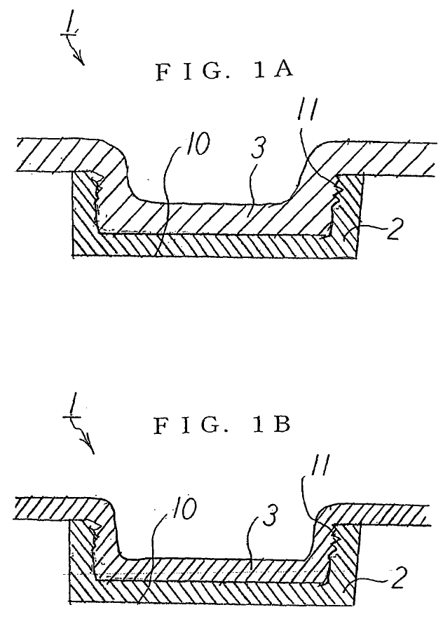

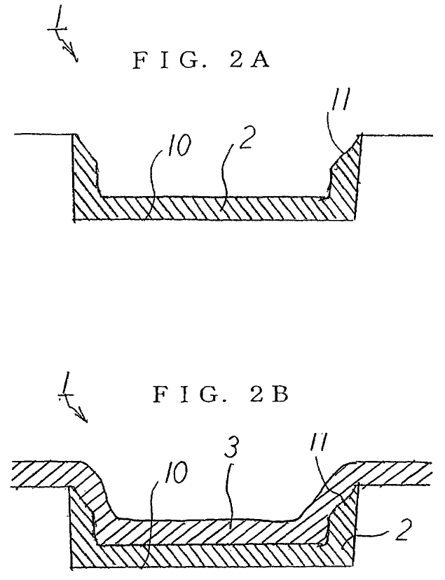

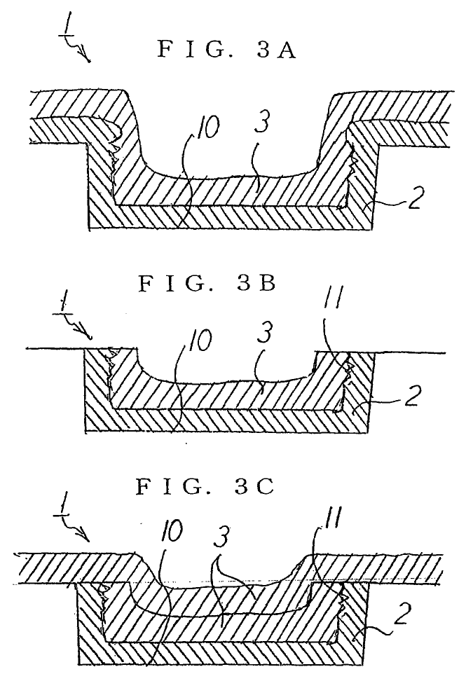

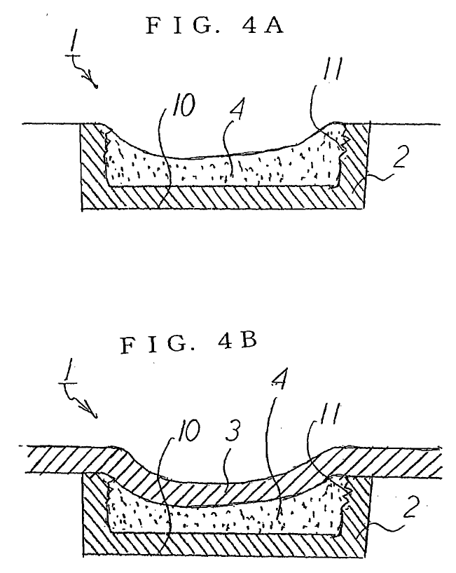

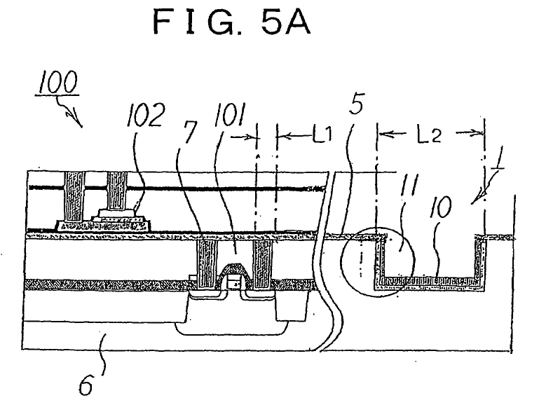

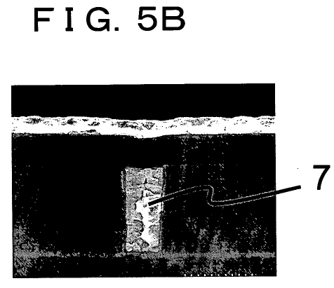

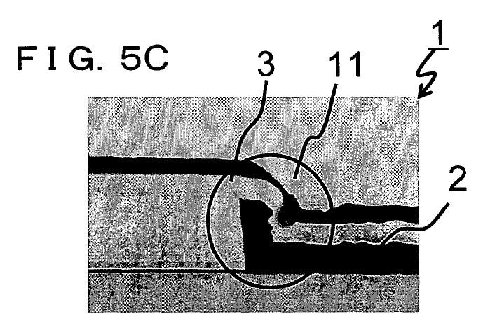

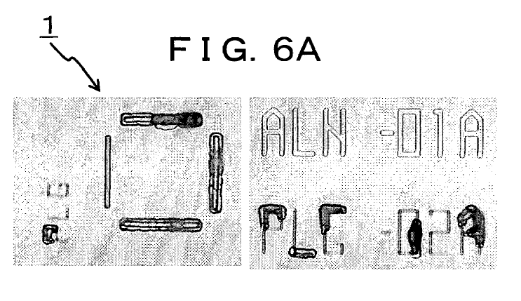

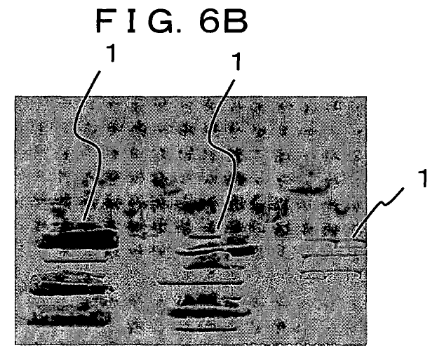

FIGS. 1A and 1B are schematic cross-sectional views of the relevant part of a first embodiment of the present invention. FIGS. 2A and 2B are schematic cross-sectional views of the relevant part of a second embodiment of the present invention. FIGS. 3A to 3C are schematic cross-sectional views of the relevant part of a third embodiment of the present invention. FIGS. 4A and 4B are schematic cross-sectional views of the relevant part of a fourth embodiment of the present invention.

### First Embodiment

FIGS. 1A and 1B are cross-sectional views each showing the part of a groove 10 of an alignment mark 1, which is essential for the production process of a FRAM, as the relevant part according to a first embodiment. In FIG. 1A, a tungsten (W) film 2 embedded in the groove 10 of the alignment mark 1 is simultaneously formed when a plug (not shown in the figure) extending from a transistor of the FRAM is formed by a damascene process including polishing by CMP. The film deposition and the polishing by CMP for the W film 2 and the plug are performed at the same time.

Furthermore, a P—SiN (SiON) oxidation-preventing film 3 for preventing the oxidation of the W film 2 is deposited on the W film 2. This oxidation-preventing film 3 is formed by a plasma chemical vapor deposition (CVD) growth method. The deposition is performed using a gas composition containing 60 sccm of SiH₄, 800 sccm of NH₃, and 500 sccm of N₂O, at a growth temperature of about 500° C., and at an RF electric power of about 50 W. The oxidation-preventing film 3 may be formed by high-density plasma CVD. The oxidation-preventing film 3 may be deposited with SiH₄ and N₂O without using NH₃.

The oxidation-preventing film 3 itself composed of P—SiN (SiON) has an excellent oxidation-preventing capability. However, the thermal contraction ratio in a heat treatment in an oxygen atmosphere is high, for example, in the range of 30% to 50%. The deposited P—SiN (SiON) film without further treatment has unsatisfactory density. The P—SiN (SiON) film is contracted by the subsequent heat treatment of a ferroelectric substance in the FRAM in an oxygen atmosphere, resulting in a degradation of the coverage. Consequently, the W film provided thereunder is oxidized.

To overcome this problem, the oxidation-preventing film 3 composed of P—SiN (SiON) is heat-treated in advance, for example, at 650° C. for five minutes. Thus, the thermally contracted dense film having satisfactory coverage is formed as shown in FIG. 1B.

In this case, when the ferroelectric substance is heat-treated in an oxygen atmosphere in the production process of the FRAM, the oxidation of the W film 2 embedded in the groove 10 of the alignment mark 1 can be prevented. Accordingly, the accuracy of the original alignment mark can be maintained.

### Second Embodiment

FIGS. 2A and 2B are cross-sectional views each showing the part of a groove 10 of an alignment mark 1, which is essential for the production process of a FRAM, as the relevant part according to a second embodiment. In FIG. 2A, a W film 2 embedded in the groove 10 of the alignment mark 1 is formed by the same process as that in the first embodiment.

The W film 2 embedded in the groove 10 of the alignment mark 1 is polished by CMP, and the W film 2 is then subjected to etch back. Consequently, as shown in FIG. 2A, irregularities at a groove peripheral part 11 of the alignment mark 1 are removed, thereby smoothening the groove peripheral part 11.

Subsequently, as shown in FIG. 2B, an oxidation-preventing film 3 composed of P—SiN (SiON) is deposited on the W film 2. Since the irregularities of the W film 2 at the groove peripheral part 11 are removed, the coverage of the oxidation-preventing film 3 in improved. As a result, when a ferroelectric substance is heat-treated in an oxygen atmosphere in the production process of the FRAM, the oxidation of the W film 2 embedded in the groove 10 of the alignment mark 1 can be prevented.

### Third Embodiment

FIGS. 3A to 3C are cross-sectional views each showing the part of a groove 10 of an alignment mark 1, which is essential for the production process of a FRAM, as the relevant part according to a third embodiment.

In FIG. 3A, a W film 2 embedded in the groove 10 of the alignment mark 1 is formed by the same process as that in the first embodiment. An oxidation-preventing film 3 composed of P—SiN (SiON) is deposited so as to cover the W film 2 embedded in the alignment mark 1.

The W film 2 and the oxidation-preventing film 3 covering the W film 2 are then polished by CMP. Consequently, as shown in FIG. 3B, irregularities of the W film 2 at the groove peripheral part 11 of the alignment mark 1 are covered by the oxidation-preventing film 3.

Subsequently, an oxidation-preventing film 3 composed of P—SiN (SiON) is again deposited thereon. Thus, the W film 2 embedded in the alignment mark 1 is doubly covered with the oxidation-preventing films 3. Accordingly, when a ferroelectric substance is heat-treated in an oxygen atmosphere in the production process of the FRAM, the oxidation of the W film 2 embedded in the groove 10 of the alignment mark 1 can be prevented.

### Fourth Embodiment

FIGS. 4A and 4B are cross-sectional views each showing the part of a groove 10 of an alignment mark 1, which is essential for the production process of a FRAM, as the relevant part according to a fourth embodiment.

In FIG. 4A, a W film 2 embedded in the groove 10 of the alignment mark 1 is formed by the same process as that in the first embodiment. Subsequently, the W film 2 embedded in the alignment mark 1 is polished by CMP.

The groove 10 of the alignment mark 1 has a depth of, for example, about 0.7 μm. Therefore, it takes a long time to completely fill the groove 10 with the W film 2. It also takes a long time to polish the outside of the groove 10 by CMP. Thus, these processes are not practical.

Consequently, an SOG film 4, which can be deposited at a high rate and can be easily polished, is formed in the groove 10 of the alignment mark 1 covered with the W film 2. Thus, irregularities of the W film 2 at the groove peripheral part 11 are covered, thereby smoothening the alignment mark 1.

Subsequently, as shown in FIG. 4B, an oxidation-preventing film 3 composed of P—SiN (SiON) is formed thereon. Thus, the W film 2 at the groove peripheral part 11 is completely covered with the oxidation-preventing film 3. As a result, when a ferroelectric substance is heat-treated in an oxygen atmosphere in the production process of the FRAM, the oxidation of the W film 2 embedded in the groove 10 of the alignment mark 1 can be prevented.

When a plasma treatment using N₂ or N₂O in the range of 200° C. to 450° C. is performed on the oxidation-preventing film composed of P—SiN (SiON), the film quality of an oxidation-preventing film can be further improved.

The oxidation-preventing film composed of P—SiN (SiON) extends to the area where the ferroelectric capacitive element serving as a FRAM memory is formed. Accordingly, when an oxide film that is composed of P—SiO and that has a refractive index in the range of 1.45 to 1.65 is formed on the oxidation-preventing film, the orientation of an electrode film that is composed of Ti, Pt, or the like and that functions as a lower electrode of the ferroelectric capacitive element can be improved.

Furthermore, a hydrogen-diffusion-preventing film composed of Al₂O₃ may be formed on the oxidation-preventing film composed of P—SiN (SiON). This structure can prevent the diffusion of hydrogen from the underlayer. Furthermore, this structure is advantageous in that the orientation of the electrode film that is composed of Ti, Pt, or the like and that functions as the lower electrode of the ferroelectric capacitive element can be improved.

As described above, in a semiconductor device produced by the method of producing a semiconductor device of the present invention, in particular, in a FRAM in which a ferroelectric substance must be heat-treated in an oxygen atmosphere, the alignment mark can be stably maintained until the end of the production process. Consequently, the present invention can provide a semiconductor device having excellent productivity.

What is claimed is:

1. A method of producing a semiconductor device having a ferroelectric capacitor used as a memory and an alignment mark prepared in a form of a groove, comprising the steps of:
embedding a tungsten(W) film in the groove of the alignment mark;
forming an oxidation-preventing film composed of P—SiN (SiON) to cover the tungsten film; and
performing heat-treatment on the oxidation-preventing film so as to thermally contract the oxidation-preventing film prior to the formation of the ferroelectric capacitor.

2. A method of producing a semiconductor device as claimed in claim 1, further comprising the steps of:
performing etch back so as to remove a part of the tungsten(W) film at the groove peripheral part of the alignment mark.

3. A method of producing a semiconductor device having a ferroelectric capacitor used as a memory and an alignment mark prepared in a form of a groove, comprising the steps of:
depositing the tungsten(W) film in the groove of the alignment mark;
polishing the tungsten(W) film by CMP to remove the tungsten(W) film outside of the alignment mark;
forming an oxidation-preventing film composed of P—SiN (SiON) to cover the tungsten film;
polishing the oxidation-preventing film by CMP to remove oxidation-preventing film outside of the alignment mark; and
forming an oxidation-preventing film composed of P—SiN (SiON) to cover the tungsten film prior to the formation of the ferroelectric capacitor.

4. A method of producing a semiconductor device having a ferroelectric capacitor used as a memory and an alignment mark prepared in a form of a groove, comprising the steps of:
depositing the tungsten (W) film in the groove of the alignment mark;
polishing the tungsten (W) film by CMP to remove the tungsten (W) film outside of the alignment mark; and
embedding an SOG film in the groove of the alignment mark.

5. A method of producing a semiconductor device as claimed in claim 1, wherein the oxidation-preventing film is a high-density plasma film.

6. A method of producing a semiconductor device as claimed in claim 1, further comprising a step of:
performing a plasma treatment using N₂ or N₂O in the range of 200° C. to 450° C. on the oxidation-preventing film.

7. A method of producing a semiconductor device as claimed in claim 1, wherein the oxidation-preventing film is formed by using SiH₄ or N₂O gas.

8. A method of producing a semiconductor device as claimed in claim 1, further comprising a step of:
forming a oxide film composed of P—SiO after forming an oxidation-preventing film composed of P—SiN (SiON),
wherein a range of refraction index of the oxide film is from 1.45 to 1.65.

9. A method of producing a semiconductor device as claimed in claim 1, further comprising a step of:
forming a hydrogen-diffusion-preventing film composed of Al₂O₃.
